(19) United States
(12) Patent Application Publication
(10) Pub. No.: US 2026/0186464 A1
(43) Pub. Date: Jul. 2, 2026

(54) METHOD AND SYSTEM FOR FORMULATING SMART IRRIGATION STRATEGY

(71) Applicant: Northwest Agriculture and Forestry University, Shanghai (CN)

(72) Inventors: Shikun SUN, Shaanxi (CN); Jina ZHANG, Shaanxi (CN); Yali YIN, Shaanxi (CN); Jiahui DONG, Shaanxi (CN); Pute WU, Shaanxi (CN); Jinfeng ZHAO, Shaanxi (CN); Yihe TANG, Shaanxi (CN); Jing XUE, Shaanxi (CN); Chao XU, Shaanxi (CN)

(21) Appl. No.: 18/697,866

(22) PCT Filed: Jan. 19, 2024
(86) PCT No.: PCT/CN2024/073287

§ 371 Date: Apr. 2, 2024

(51) Int. Cl. G05B 19/042

(52) U.S. Cl. CPC G05B 19/042; G05B 2219/2625

(57) ABSTRACT

The present disclosure provides a method and system for formulating a smart irrigation strategy. The method includes: determining, based on the current agricultural state, a current irrigation strategy based on a preset irrigation decision-making model and a Q-learning smart body; performing irrigation simulation on the target planting area, to obtain a reward value for irrigation and a next agricultural state; the current agricultural state, the current irrigation strategy, the reward value for irrigation, and the next agricultural state form an experience quaternion; and a plurality of experience quaternions constitute an experience pool; and taking a randomly sampled experience quaternion in the experience pool as a training sample, and training the Q-learning smart body, to obtain a table of optimal Q values for irrigation, where the table of optimal Q values for irrigation is used to determine an optimal irrigation strategy based on any agricultural state of the target planting area.

### CROSS REFERENCE TO RELATED APPLICATION

This patent application is a national stage application of International Patent Application No. PCT/CN2024/073287, filed on Jan. 19, 2024.

### TECHNICAL FIELD

The present disclosure relates to the field of agricultural irrigation technologies, and in particular, to a method and system for formulating a smart irrigation strategy.

### BACKGROUND

In the field of agricultural irrigation information technologies, intelligent algorithms such as a radial basis function (RBF) neural network, a decision tree, and a model predictive control (MPC) promote design and optimization of an irrigation system. However, considering inherent complexity of irrigation system control, a simple and accurate system model is developed depending on rich historical data sets. Although a simplified model is more convenient in use, oversimplification may reduce a capability of the simplified model to accurately describe system dynamics. As a result, there is a gap between a control output and a stated objective. As a typical model-free learning strategy, a reinforcement learning algorithm provides a methodology for resolving optimization problems of a complex irrigation system. In view of a strong adaptive capability of reinforcement learning in adapting to complex environments and learning to control, such algorithm shows great potential when dealing with complex models such as the irrigation system. Therefore, it is necessary to perform research on the reinforcement learning algorithm, to optimize intelligent decision-making in the irrigation system and promote integration and collaborative work of the reinforcement learning algorithm in practical application.

### SUMMARY

An objective of the present disclosure is to provide a method and system for formulating a smart irrigation strategy, to effectively obtain an accurate irrigation strategy and to irrigate a planting area.

To achieve the above objective, the present disclosure provides the following technical solutions.

According to a first aspect, the present disclosure provides a method for formulating a smart irrigation strategy and for irrigating a planting area. The method includes:
obtaining a current agricultural state of a target planting area, where the current agricultural state includes meteorological data, soil data, crop parameters, and field management data;
determining, based on the current agricultural state, a current irrigation strategy based on a preset irrigation decision-making model and a Q-learning smart body;
performing irrigation simulation on the target planting area based on the current irrigation strategy, to obtain a reward value for irrigation and a next agricultural state, where the reward value for irrigation is determined based on a crop yield after irrigation, a crop water demand, and annual economic costs; the current agricultural state, the current irrigation strategy, the reward value for irrigation, and the next agricultural state form an experience quaternion; and a plurality of experience quaternions constitute an experience pool;
taking a randomly sampled experience quaternion in the experience pool as a training sample, and training the Q-learning smart body, to obtain a table of optimal Q values for irrigation, where the table of optimal Q values for irrigation is used to determine an optimal irrigation strategy based on any agricultural state of the target planting area; and
irrigating the target planting area based on the table of optimal Q values.

According to a second aspect, the present disclosure provides a system for formulating a smart irrigation strategy and for irrigating a planting area. The system includes:
a current state obtaining module, configured to obtain a current agricultural state of a target planting area, where the current agricultural state includes meteorological data, soil data, crop parameters, and field management data;
a current irrigation strategy determining module, configured to: determine, based on the current agricultural state, a current irrigation strategy based on a preset irrigation decision-making model and a Q-learning smart body;
an experience pool construction module, configured to: perform irrigation simulation on the target planting area based on the current irrigation strategy, to obtain a reward value for irrigation and a next agricultural state, where the reward value for irrigation is determined based on a crop yield after irrigation, a crop water demand, and annual economic costs; the current agricultural state, the current irrigation strategy, the reward value for irrigation, and the next agricultural state form an experience quaternion; and a plurality of experience quaternions constitute an experience pool; and
a module for determining a table of optimal Q values, configured to: take a randomly sampled experience quaternion in the experience pool as a training sample, and train the Q-learning smart body, to obtain a table of optimal Q values for irrigation, where the table of optimal Q values for irrigation is used to determine an optimal irrigation strategy based on any agricultural state of the target planting area and where the table of optimal Q values is used as a basis to implement irrigation of the target planting area.

According to specific embodiments provided in the present disclosure, the present disclosure has the following technical effects:

The present disclosure provides a method and system for formulating an intelligent irrigation strategy and for irrigating a planting area. Meteorological factors, soil data, crop parameters, and field management information are taken into account, and are incorporated into a calculation framework of an irrigation decision-making model. An irrigation strategy is optimized by calculating and analyzing a crop yield, a crop water demand, and annual economic costs of the irrigation system, to promote overall improvement in efficiency and economic benefits of the irrigation system.

### BRIEF DESCRIPTION OF THE DRAWINGS

FIG. 1 is a schematic flowchart of a method for formulating a smart irrigation strategy according to the present disclosure;

FIG. 2 is a principle diagram of reinforcement learning;

FIG. 3 is a principle diagram of a Q-learning algorithm;

FIG. 4 is a simulation diagram of irrigation decision-making based on Q-learning;

FIG. 5 is a co-simulation diagram of Python-AquaCrop based on Q-learning;

FIG. 6 is a diagram of a collaborative simulation process based on Q-learning; and

FIG. 7 is a diagram of an iteration process based on Q-learning.

### DETAILED DESCRIPTION OF THE EMBODIMENTS

To perform in-depth analysis on control decision-making of an irrigation system, and perform analysis on impact of different irrigation decision-making on a crop yield, a crop water demand, and economic benefits, the present disclosure provides a method and system for formulating an intelligent irrigation strategy and for irrigating a planting area, and develops a Python-AquaCrop co-simulation model incorporating a highly efficient Q-learning algorithmic framework, to provide a new research perspective and technological path for scientific research and development of a large-scale irrigation system.

### Embodiment 1

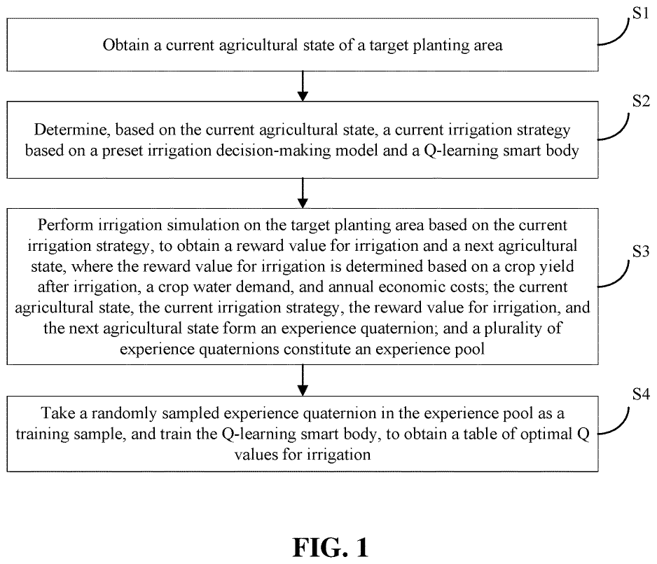

As shown in FIG. 1, the present disclosure provides a method for formulating a smart irrigation strategy. The method includes:
S1: Obtain a current agricultural state of a target planting area. The current agricultural state includes meteorological data, soil data, crop parameters, and field management data. The meteorological data includes precipitation, an air temperature, and a sunshine duration. The crop parameters include a fertility parameter and yield data. The parameters are used to accurately perform accurate modeling on a crop water demand and response in an agricultural production process.

Firstly, meteorological station data of the target planting area is collected from the China Meteorological Data Service Centre (http://data.cma.cn/), including key meteorological variables such as precipitation, an air temperature, and a sunshine duration. The meteorological station data provides necessary basic information for assessing meteorological conditions. Then, a Penman-Monteith formula is used to estimate a potential evapotranspiration ET₀ from a reference crop:

$$E {T}_{0} = \frac{0.408 Δ ( {R}_{n} - G ) + γ \frac{900}{T + 273} {u}_{2} ( {e}_{s} - {e}_{a} )}{Δ + γ ( 1 + 0.34 {u}_{2} )} ,$$

where
Rₙ represents net radiation on a crop surface; G represents a soil heat flux; T represents a mean air temperature; u₂ represents a wind speed at a height of 2 m; γ represents a hygrometer constant; eₛ represents a saturation pressure of water vapor in air; eₐ represents an actual pressure of water vapor in air; and Δ represents a slope of a relationship curve of the saturation pressure of water vapor and a temperature.

This formula considers combined impact of a plurality of meteorological factors and provides a preliminary assessment on a crop water demand. It should be noted that, in a physiological process of crop growth, consumption of water by evapotranspiration directly affects the crop water demand. Because supply of water is closely related to a crop yield, economic benefits of agriculture are affected. Therefore, a potential evapotranspiration of the crop calculated by the formula may be used as a reference for a reward value while a weight is determined. In addition, the crop yield, the crop water demand, and the annual economic costs are mutually restricted and affected, and the potential evapotranspiration of the crop is the basis for mutual constraints of the crop yield, the crop water demand, and the annual economic costs.

According to the present disclosure, soil data of a planting area is extracted, which is essential for understanding a capability of retaining water in soil and absorbing water by the crop. In addition, the crop parameters and the field management information directly affect irrigation requirements and prediction on a yield, and are also taken into account. A comprehensive and accurate agricultural model is established through data aggregation and analysis, to provide a scientific basis for formulating an optimal irrigation strategy.
S2: Determine, based on the current agricultural state, a current irrigation strategy based on a preset irrigation decision-making model and a Q-learning smart body. The preset irrigation decision-making model includes six irrigation strategies, and the six irrigation strategies form a parameter set for selection of the irrigation strategies in the model.

First irrigation strategy: rain-fed irrigation (non irrigation).

Second irrigation strategy: triggering irrigation when water content of soil in a root zone of a crop is lower than a preset threshold.

Third irrigation strategy: performing irrigation at a preset day interval, that is, periodic irrigation.

Fourth irrigation strategy: a predefined irrigation schedule.

Fifth irrigation strategy: performing daily irrigation to fill all gaps between soil layers and maintain soil moisture at a preset moisture value.

Sixth irrigation strategy: performing everyday irrigation until a preset depth of the soil is reached.

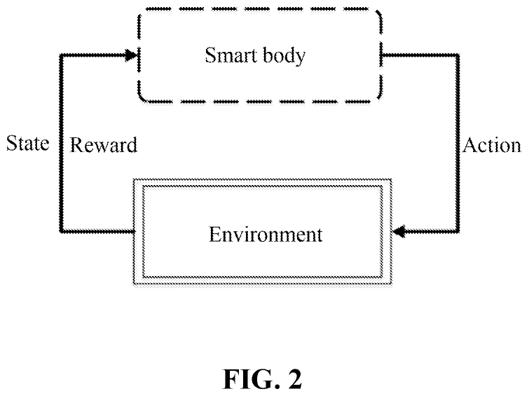

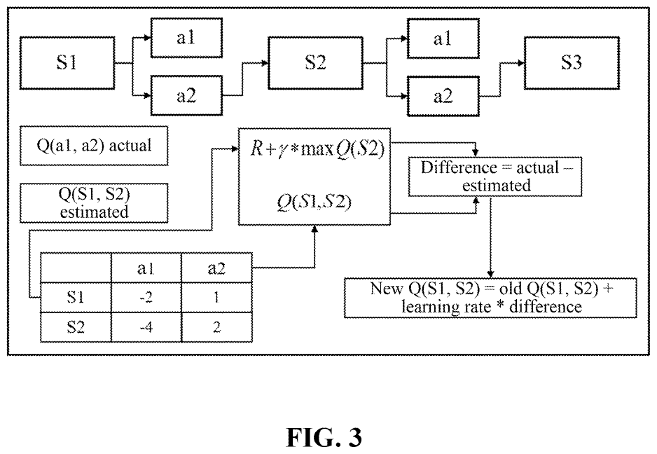

Q-learning smart body: As shown in FIG. 2 and FIG. 3, starting from a random strategy, a table of Q values is iteratively updated through interaction with an environment. Balance is sought between exploration (trying a new action) and utilization (choosing a best action based on known information). The Q-learning smart body performs an action in the environment and accumulates experience based on an observed reward and new state, to gradually optimize the table of Q values, and tend to an optimal strategy by reducing a difference between an estimated Q value and an actual reward.

In the field of reinforcement learning, especially in a framework of a Q-learning algorithm, a strategy is a decision-making guide and specifies an action for each state that may be encountered. The strategy is usually represented by a symbol π, and is mapping from state space to action space (π: S→A). The strategy specifies an action a to each state s, to guide the Q-learning smart body to make a decision in the environment, as shown in the following formula:

$$π ( a \vert s ) = P ( A = {a}_{t} \vert S = {S}_{t} ) ,$$

where

P represents conditional probability of outputting a control action, A represents the control action, and S represents a state.

In a framework of reinforcement learning, merit of the strategy π is determined by assessing an expected value of the strategy a to generate a cumulative reward. The cumulative reward is a sum of future rewards that may be obtained based on a stated strategy from an initial state, and maps a potential gain from long-term execution of the strategy. To estimate the expected value of the cumulative reward, researchers usually depend on an experience track, that is, an action-state-reward sequence. The experience track chronologically records an implementation track of a particular strategy in the environment, as shown in the following formula:

$${G}_{t} = {\sum }_{k = 0}^{T} {β}^{k} {r}_{t + k} ,$$

where
Gₜ represents the cumulative reward, r represents an immediate reward obtained at a current time step, and β represents a discount coefficient.

A state value function defines expectation of obtaining cumulative rewards by following the strategy π in a state Sₜ. This function measures state quality under a stated strategy, and is reflected as mathematical expectation of future cumulative rewards that may be obtained from the state, as shown in the following formula:

$${v}_{π} ( s ) = {\hat{E}}_{π} ( {G}_{t} \vert S = {S}_{t} ) ,$$

where
a state-action value function is also referred to an action value function. An expected value of the function represents an expected cumulative reward for choosing an action in the state Sₜ and performing the action aₜ by following the strategy π, as shown in the following formula:

$${Q}_{π} ( s , a ) = {\hat{E}}_{π} ( {G}_{t} \vert S = {S}_{t} , A = {a}_{t} ) ,$$

where

The state-action value function provides an assessment on an expected benefit of performing a particular action in a particular state, to select an optimal decision in the state space and the action space.

In the field of reinforcement learning, a fundamental goal is to discover or approximate an optimal strategy, that is, to find a decision-making rule that maximizes the expected cumulative reward. The goal is achieved by incrementally improving strategy performance, and is typically based on estimation of an expected reward associated with each state-action. In a process of improving the strategy, the strategy is usually improved depending on a dominant function. The dominant function measures expected benefit of performing the particular action aₜ in the state Sₜ under the stated strategy π. The dominant function may be calculated based on a difference between the state-value function and the state-action value function, and a formula is as follows:

$${A}_{π} ( s , a ) = {Q}_{π} ( s , a ) - {v}_{π} ( s ) .$$

Q-learning is a model-free reinforcement learning algorithm, and centers on learning an optimal strategy in a decision-making process by directly interacting with the environment. The optimal strategy is a sequence of actions taken in the particular state, aiming to optimize expectation of the future cumulative reward. Pseudo-code is as follows:

Initialize the table of Q values, and initialize all Q values (s, a) to 0, where s represents the state and a represents the action.

Set a learning rate alpha (usually a small positive number).

Set a discount factor beta (usually between 0 and 1).

Set exploration probability epsilon (usually a small positive number, used to explore a new action).

For episode: i=0, 1, 2 . . . do.

Start from the initial state.

Repeat the following steps when a current state is not a termination state:

Select an action a according to an epsilon-greedy strategy.

Randomly select an action with the probability epsilon.

If the action is not randomly selected with the probability epsilon, select an action with a largest Q value, and calculate a loss function according to a small quantity of steps.

Perform the action a, and observe a reward r and a new state sₜ₊₁.

Update the table of Q values:

$$Q ( {s}_{t} , {a}_{t} ) ← Q ( {s}_{t} , {a}_{t} ) + \partial [ {r}_{t + 1} + β {max}_{a} Q ( {s}_{t + 1} , a ) - Q ( {s}_{t} , {a}_{t} ) ] .$$

Update a state s to sₜ₊₁.

End for.

A final learned table of Q values includes a Q value of each state-action pair, and is used to select the optimal strategy and as a basis to irrigate a planting area.

Q (sₜ,aₜ) represents a Q value under a current agricultural state sₜ and an action aₜ, and the action means the irrigation strategy; ∂ represents a learning rate; β represents a discount coefficient, and is used to measure a current value of a future reward; ₐ^{max}Q(sₜ₊₁, a) represents a maximum value of Q values for all possible actions in a next agricultural state sₜ₊₁, characterizing an optimal expected value of a future action; and rₜ₊₁ represents a next reward value for irrigation.

Q-learning shows its computational efficacy in a plurality of dimensions: model independence; strategy orthogonality; efficient processing on a delayed reward; and an offline learning capability. The Q-learning algorithm stores the Q values in a table, so that the Q-learning algorithm is appropriate for small discrete state space and action space. In the present disclosure, a developed framework of the Q-learning algorithm includes two parts, namely, a decision-making loop and a value assessment loop. The decision-making loop is responsible for performing the current strategy and environment exploration. The value assessment loop adjusts and optimizes the strategy based on an exploration result. Detailed steps of the Q-learning algorithm are as follows:

Performing of decision-making: Continuously monitor an environment state, and obtain decision-making for an action based on a greedy strategy. In addition, record state transfer and reward feedback.

Experience playback: Assess the Q values of the state-action pair by randomly sampling stored experience data, and update a value function.

Updating of the strategy: Adjust and perform the strategy based on the Q values, and describe the learning rate as an adjustment parameter for optimization of the strategy, aiming to optimize a long-term cumulative reward.
S3: Perform irrigation simulation on the target planting area based on the current irrigation strategy, to obtain a reward value for irrigation and a next agricultural state. The reward value for irrigation is determined based on a crop yield after irrigation, a crop water demand, and annual economic costs. The current agricultural state, the current irrigation strategy, the reward value for irrigation, and the next agricultural state form an experience quaternion. A plurality of experience quaternions constitute an experience pool.

For an irrigation system considering the Q-learning algorithm, four types of data, namely, meteorological factors, soil data, crop parameters, and field management information that are closely related to optimization of a control strategy of the irrigation system, are used as state variables. The integration of the state variables is the basis of state space of the irrigation system, and provides information support for optimization and control of decision-making. The crop water demand is determined by an irrigation strategy. Therefore, the irrigation strategy is used as a control action for reinforcement learning, and optimal decision-making is performed based on the Q-learning algorithm.

The crop yield, the crop water demand, and the annual economic costs of the irrigation system are taken as main variables of a reward function, aiming to guide optimization of the irrigation system. A calculation formula for a reward value for irrigation is as follows:

$$Reward = - {μ}_{1} Q V - {μ}_{2} GY - {μ}_{3} CT ,$$

where

Reward represents the reward value for irrigation; μ₁, μ₂, and μ₃ represent weight coefficients, reflecting relative importance and priority in optimization of the control strategy for irrigation, and values of the three weight coefficients may be determined based on the potential evapotranspiration of the crop; and QV represents the crop water demand, GY represents the crop yield, and CT represents the annual economic costs.
S4: Take a randomly sampled experience quaternion in the experience pool as a training sample, and train the Q-learning smart body, to obtain a table of optimal Q values for irrigation. The table of optimal Q values for irrigation is used to determine an optimal irrigation strategy based on any agricultural state of the target planting area and where the table of optimal Q values is used as a basis to implement irrigation of the target planting area.

At present, an AquaCrop-OSPy extension module developed in Python provides AquaCrop with a set of standardized interfaces, to implement model data exchange and co-simulation. Therefore, accessibility and integration of a data structure between AquaCrop and Python are improved, and efficient implementation of model exchange and co-simulation is promoted. This integrated architecture supports AquaCrop to perform setting of variables and operation of reinforcement learning of an irrigation system model in a Python environment, and promotes development and optimization of a complex control strategy.

According to the present disclosure, an AquaCrop co-simulation model is constructed based on Python and centered on the Q-learning algorithm, so that an optimization and control capability of the model is improved, an optimal control strategy for a specific irrigation system is effectively output, and potential of reinforcement learning in the field of agricultural water management is shown. Operational efficiency of the irrigation system is improved, which is expected to achieve a higher level of automated management and intelligent management. The co-simulation model is capable of assessing performance of the control strategy in an OpenAI Gym environment, which facilitates debugging and shows excellent scalability. Based on the Q-learning algorithm, a co-simulation platform implements appropriateness of the crop yield and the crop water demand through continuous interaction with the environment and iterative learning, and accurately outputs the optimal control strategy of the irrigation system based on maximum economic benefits.

According to the present disclosure, a co-simulation process based on Q-learning involves three stages: (1) developing a simulation environment integrating Python and AquaCrop, aiming to simulate an irrigation decision-making system model; (2) adjusting parameter configurations for the Q-learning algorithm, and optimizing internal variables of the algorithm, to ensure that a control system meets preset performance requirements; and (3) training a Q-learning algorithm model, and assessing a latest control strategy output by the Q-learning smart body, to verify effectiveness and applicability of the Q-learning algorithm in optimizing the control strategy of the irrigation system.

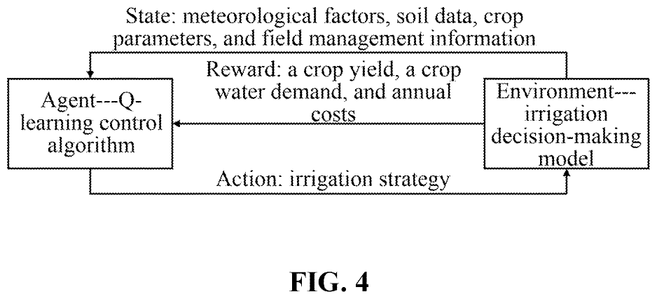

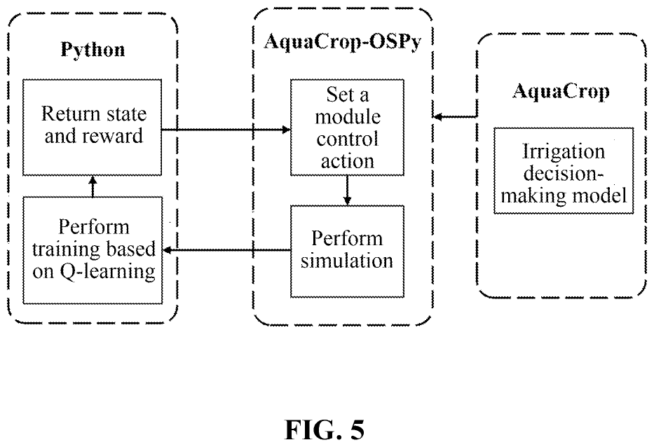

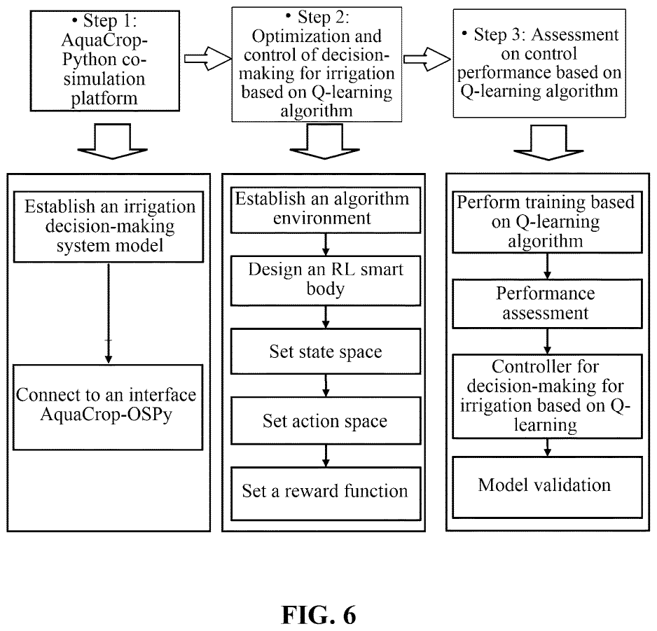

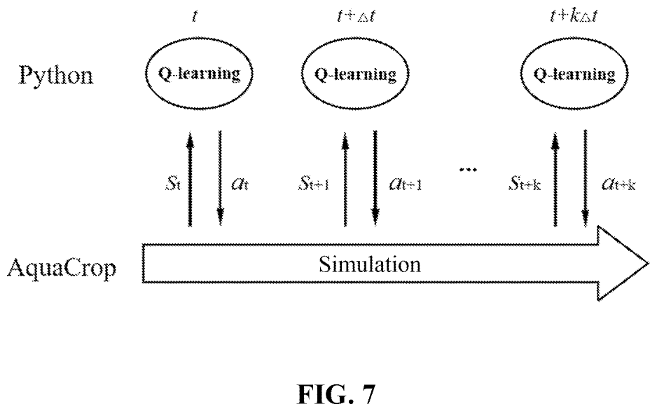

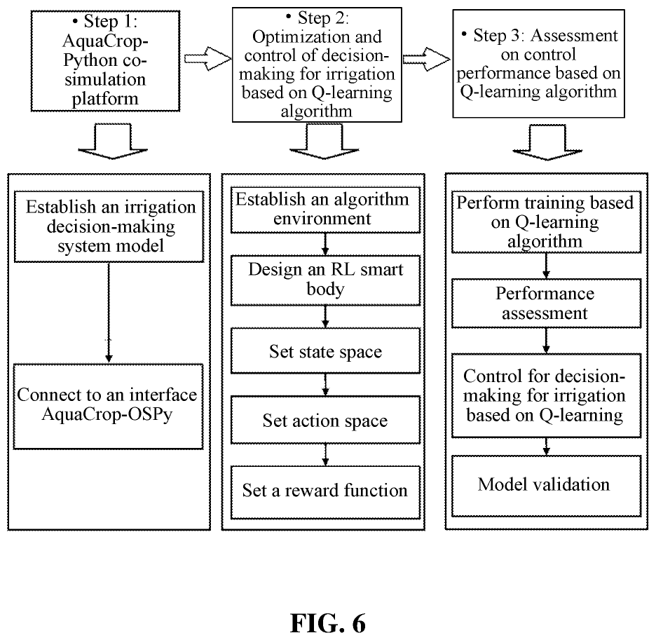

As shown in FIG. 4, FIG. 5, FIG. 6, and FIG. 7, the method includes:
(1) Construct a preset irrigation decision-making model by AquaCrop software, and collect a current agricultural state of a target planting area.
(2) Construct a Q-learning smart body and an AquaCrop-OSPy module by Python software. In a Python environment, a program path connected to an AquaCrop model interface is constructed, to develop an integrated simulation framework. The integrated simulation framework that uses the AquaCrop software to dynamically monitor and analyze effect of an irrigation strategy under impact of changed environmental conditions and management actions, and dynamically monitor and analyze daily changes in water flux to a crop.
(3) The Q-learning smart body written in Python continuously and dynamically interacts with an AquaCrop simulation environment, to implement synchronization and exchange of real-time data. The AquaCrop-OSPy module receives initialization data of the Q-learning smart body in the Python software, and then determines a current irrigation strategy (that is, a control action) in combination with a preset irrigation decision-making model constructed in the AquaCrop software and the current agricultural state.
(4) In the AquaCrop-OSPy module, irrigation simulation is performed based on the current irrigation strategy, and a simulation result is sent to the Q-learning smart body in the Python software, to perform iteration once, output a reward value for irrigation and a next agricultural state to the AquaCrop-OSPy module, and reset the current irrigation strategy in the AquaCrop-OSPy module. This cycle is repeated until the algorithm model converges and an optimal irrigation strategy is output. An iteration period is mainly limited by a running time of AquaCrop simulation. To standardize the iteration period and ensure synchronization, an iteration time step between the AquaCrop simulation and the Q-learning smart body is set to 10 seconds, that is, a time increment for each iteration is Δt=10 seconds.

The co-simulation platform obtained through construction makes full use extensive data structure resources provided by Python. Therefore, variables are defined and calculated based on the Q-learning algorithm in a working environment of Python, and limitation of preset control logic of the AquaCrop software is overcome.

### Embodiment 2

To implement the technical solution in Embodiment 1 and implement the corresponding functions and technical effect, an embodiment further provides a system for formulating a smart irrigation strategy and for irrigating a planting area. The system includes a current state obtaining module, a current irrigation strategy determining module, an experience pool construction module, and a module for determining a table of optimal Q values.

The current state obtaining module is configured to obtain a current agricultural state of a target planting area, where the current agricultural state includes meteorological data, soil data, crop parameters, and field management data.

The current irrigation strategy determining module is configured to: determine, based on the current agricultural state, a current irrigation strategy based on a preset irrigation decision-making model and a Q-learning smart body.

The experience pool construction module is configured to: perform irrigation simulation on the target planting area based on the current irrigation strategy, to obtain a reward value for irrigation and a next agricultural state, where the reward value for irrigation is determined based on a crop yield after irrigation, a crop water demand, and annual economic costs; the current agricultural state, the current irrigation strategy, the reward value for irrigation, and the next agricultural state form an experience quaternion; and a plurality of experience quaternions constitute an experience pool.

The module for determining a table of optimal Q values is configured to: take a randomly sampled experience quaternion in the experience pool as a training sample, and train the Q-learning smart body, to obtain a table of optimal Q values for irrigation, where the table of optimal Q values for irrigation is used to determine an optimal irrigation strategy based on any agricultural state of the target planting area and where the table of optimal Q values is used as a basis to implement irrigation of the target planting area.

Each embodiment in this specification is described in a progressive mode, each embodiment focuses on differences from other embodiments, and references can be made to each other for the same and similar parts between embodiments. Since the system disclosed in an embodiment corresponds to the method disclosed in an embodiment, the description is relatively simple, and for related contents, references can be made to the description of the method.

Particular examples are used herein for illustration of principles and implementation modes of the present disclosure. The descriptions of the above embodiments are merely used for assisting in understanding the method of the present disclosure and its core ideas. In addition, those of ordinary skill in the art can make various modifications in terms of particular implementation modes and the scope of application in accordance with the ideas of the present disclosure. In conclusion, the content of the description shall not be construed as limitations to the present disclosure.

1. A method for irrigating a planting area, comprising:
obtaining a current agricultural state of a target planting area, wherein the current agricultural state comprises meteorological data, soil data, crop parameters, and field management data;
determining, based on the current agricultural state, a current irrigation strategy based on a preset irrigation decision-making model and a Q-learning smart body;
performing irrigation simulation on the target planting area based on the current irrigation strategy, to obtain a reward value for irrigation and a next agricultural state, wherein the reward value for irrigation is determined based on a crop yield after irrigation, a crop water demand, and annual economic costs; the current agricultural state, the current irrigation strategy, the reward value for irrigation, and the next agricultural state form an experience quaternion; and a plurality of experience quaternions constitute an experience pool;
taking a randomly sampled experience quaternion in the experience pool as a training sample, and training the Q-learning smart body, to obtain a table of optimal Q values, wherein the table of optimal Q values is used to determine an optimal irrigation strategy based on any agricultural state of the target planting area; and
irrigating the target planting area based on the table of optimal Q values.

2. The method according to claim 1, wherein the preset irrigation decision-making model comprises six irrigation strategies;
a first irrigation strategy: rain-fed irrigation;
a second irrigation strategy: triggering irrigation when water content of soil in a root zone of a crop is lower than a preset threshold;
a third irrigation strategy: performing irrigation at a preset day interval;
a fourth irrigation strategy: a predefined irrigation schedule;
a fifth irrigation strategy: performing daily irrigation to fill all gaps between soil layers and maintain soil moisture at a preset moisture value; and
a sixth irrigation strategy: performing everyday irrigation until a preset depth of the soil is reached.

3. The method according to claim 1, wherein a calculation formula of the reward value for irrigation is as follows:
$$Reward = - {μ}_{1} Q V - {μ}_{2} GY - {μ}_{3} CT ,$$
wherein
Reward represents the reward value for irrigation, μ₁, μ₂, and μ₃ represent weight coefficients, QV represents the crop water demand, GY represents the crop yield, and CT represents the annual economic costs.

4. The method according to claim 1, wherein a training update formula for training performed on the Q-learning smart body is as follows:
$$Q ( {s}_{t} , {a}_{t} ) ← Q ( {s}_{t} , {a}_{t} ) + \partial [ {r}_{t + 1} + β {max}_{a} Q ( {s}_{t + 1} , a ) - Q ( {s}_{t} , {a}_{t} ) ] ,$$
wherein
Q (sₜ,aₜ) represents a Q value under a current agricultural state sₜ and an action aₜ, and the action means the irrigation strategy; ∂ represents a learning rate; β represents a discount coefficient, and is used to measure a current value of a future reward;
$${max}_{a} Q ( {s}_{t + 1} , a )$$
represents a maximum value of Q values for all possible actions in a next agricultural state sₜ₊₁, characterizing an optimal expected value of a future action; and rₜ₊₁ represents a next reward value for irrigation.

5. The method according to claim 1, wherein the method further comprises:
constructing the preset irrigation decision-making model by AquaCrop software, and collecting the current agricultural state of the target planting area;
constructing the Q-learning smart body and an AquaCrop-OSPy module by Python software;
receiving, by the AquaCrop-OSPy module, initialization data of the Q-learning smart body in the Python software, and determining the current agricultural state based on the current irrigation strategy and the preset irrigation decision-making model in the AquaCrop software; and
performing irrigation simulation based on the current irrigation strategy in the AquaCrop-OSPy module, and sending a simulation result to the Q-learning smart body in the Python software for performing iteration once, outputting the reward value for irrigation and the next agricultural state to the AquaCrop-OSPy module, and resetting the current irrigation strategy in the AquaCrop-OSPy module.

6. The method according to claim 1, wherein the meteorological data comprises precipitation, an air temperature, and a sunshine duration; and the crop parameters comprise a fertility parameter and yield data.

7. (canceled)
